(19) United States
(12) Patent Application Publication
(10) Pub. No.: US 2004/0257882 A1
(43) Pub. Date: Dec. 23, 2004

(54) Bias generation having adjustable range and resolution through metal programming

(76) Inventors: Blaine Stackhouse, Fort Collins, CO (US); John Wuu, Fort Collins, CO (US); Donald R. Weiss, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/600,875

(22) Filed: Jun. 20, 2003

(51) Int. Cl. G11C 29/00

(52) U.S. Cl. 365/189.09; 365/156; 365/154; 365/201

(57) ABSTRACT

The present invention uses metal programming to facilitate modifying a range and/or resolution of a bias voltage output signal generated by a programmable bias generator. A metal-programmable (MP) bias generator includes a MP transistor in the bias generator. The MP transistor includes either or both of a MP pull-up transistor and a MP pull-down transistor, each having a respective ON state resistance. A method of modifying the bias generator includes metal programming either or both of the MP pull-up transistor and the MP pull-down transistor, such that the respective ON state resistance of the corresponding metal-programmed transistor is combined with an effective ON state resistance of circuitry of the bias generator. The combined ON state resistances change one or both of the range and the resolution of a set of available magnitudes of the bias voltage output signal.

### TECHNICAL FIELD

The invention relates to integrated circuits (IC). In particular, the invention relates to built-in self-test (BIST) used with static random access memory (SRAM).

### BACKGROUND OF THE INVENTION

Among the typical tests that are performed on SRAM arrays are tests for memory cell data retention faults (DRFs) and memory cell stability faults. In particular, DRFs and stability faults often result from variations in manufacturing materials and processes. In the past, DRF and stability fault testing has been largely functional in nature. Namely, a read/write algorithm is developed that functionally exercises the SRAM. The read/write algorithm is then executed by a memory test system external to the IC. From the results of the functional testing, an attempt is made to deduce DRFs and stability faults for individual memory cells in the SRAM.

Recently, several test methodologies have been developed that directly test for such failures instead of inferring the failures from functional tests. Moreover, some of these test methodologies are well-suited to being implemented as a built-in self-test (BIST), such that the cost and time associated with testing for DRF and stability faults using an external memory test system are reduced or effectively eliminated. One such methodology known as Weak Write Test Mode (WWTM) is disclosed by Banik et al., U.S. Pat. No. 5,559,745, incorporated herein by reference.

When testing an SRAM with WWTM, an attempt is made to overwrite a data value stored in a memory cell using a “weak” write value or signal. The weak write signal is only capable of overwriting the stored value in the memory cell if the memory cell is unstable or defective. Thus, if the weak write test is successful, a defect in the memory cell is indicated. An unsuccessful weak write test indicates a healthy memory cell, at least with respect to stability and DRFs.

Weiss et al., U.S. Pat. No. 6,192,001 B1, incorporated herein by reference, disclose a WWTM approach that integrates a weak write driver functionality into an existing conventional column-associated write driver of the SRAM. According to Weiss et al., only two additional transistors are added to each conventional write driver in each set of columns as opposed to six transistors per column according to Banik et al. A set of columns is one or more columns depending on whether or not column multiplexing is employed in the SRAM. In particular, a first or weak write pull-down transistor is added that modifies a level of an output signal of the write driver when in WWTM and a second or bypass pull-down transistor is added that essentially bypasses the first transistor thereby facilitating a normal or strong write output signal to be produced by the write driver when not in WWTM.

Unfortunately, sizing of the weak write pull-down transistor of Weiss et al. presents certain practical difficulties in IC manufacturing. In particular, the weak write pull-down transistor must be big or strong enough to insure that the WWTM write driver output signal adequately exercises the memory cells of the SRAM, allowing for reliable detection of defective memory cells. Simultaneously, the weak write pull-down transistor must be small or weak enough such that the WWTM write driver output signal is not capable of overwriting data in healthy memory cells thereby producing false detection of defects.

In practice, the weak write pull-down transistor sizing is sensitive to variables and tolerances of a given manufacturing line and/or inadequacies of a design simulation to account for such variables and tolerances. Thus, many memory design and prototype iterations may be necessary to produce a properly sized weak write pull-down transistor. Moreover, each time the IC design is changed and/or the manufacturing process/line is changed or modified, the iterative design process typically must be repeated.

Accordingly, it would be advantageous to have a WWTM implementation that provided a modifiable range or extent of a programmable bias voltage used in WWTM testing of SRAMs. In addition, providing a way to increase a resolution of the programmable bias voltage without requiring an increase in a number of selection inputs likewise would be advantageous. Such a modifiable range and an increased resolution of the programmable bias voltage would address a long-felt need in the area of WWTM testing of SRAMs.

### SUMMARY OF THE INVENTION

The present invention facilitates a modification or a shift in a range and/or an adjustment of a resolution of a bias voltage output signal generated by a programmable bias generator. In particular, metal programming is employed to selectively add one or more transistors to the bias generator during circuit manufacture. By the selective addition of the transistor(s) through metal programming, the range modifications and/or resolution adjustments are realized. A programmable bias voltage having the modified range and/or adjustable resolution is employed to implement a test of static random access memory (SRAM).

In one aspect of the invention, a metal-programmable bias generator for testing of a static random access memory (SRAM) is provided. The bias generator comprises means for adjusting a set of available magnitudes of a bias voltage output signal at an output the bias generator using metal programming. In some embodiments, the means for adjusting comprises a metal-programmable transistor in the bias generator. The metal-programmable transistor comprising either or both of a metal-programmable pull-up transistor and a metal-programmable pull-down transistor that change one or both of a range and a resolution of the set of available magnitudes when the metal-programmable transistor is metal programmed to circuitry of the bias generator.

In another aspect of the invention, a method of modifying a set of available magnitudes of a bias voltage of a programmable bias generator is provided. The method of modifying comprises providing a metal-programmable transistor in the bias generator, and metal programming the metal-programmable transistor to connect the transistor to circuitry of the bias generator. A corresponding ON state resistance of the metal-programmed transistor is combined with an effective ON state resistance of the circuitry to modify the available magnitudes of the set.

Certain embodiments of the present invention have other features in addition to and in lieu of the features described hereinabove. These and other features and advantages of the invention are detailed below with reference to the following drawings.

### BRIEF DESCRIPTION OF THE DRAWINGS

The various features and advantages of the present invention may be more readily understood with reference to the following detailed description taken in conjunction with the accompanying drawings, where like reference numerals designate like structural elements, and in which:

FIG. 1 illustrates a block diagram of a metal-programmable weak write test mode (MPWWTM) bias generator according to an embodiment of the present invention.

FIG. 2A illustrates a schematic of a metal-programmable (MP) pull-up transistor of the MPWWTM bias generator of FIG. 1 depicting a transition through metal programming from an exemplary ‘isolated’ configuration to a connected configuration.

FIG. 2B illustrates a schematic of a metal-programmable (MP) pull-down transistor of the MPWWTM bias generator of FIG. 1 depicting a transition through metal programming from an exemplary ‘isolated’ configuration to a connected configuration.

FIG. 3A illustrates a graph of exemplary bias voltage V_{bias} magnitudes versus selection inputs for a metal-programmable pull-up transistor according to an embodiment of the present invention.

FIG. 3B illustrates a graph of exemplary bias voltage V_{bias} magnitudes versus selection inputs for a metal-programmable pull-down transistor according to an embodiment of the present invention.

FIG. 3C illustrates a graph of exemplary generated bias voltage V_{bias} magnitudes versus selection inputs for both a metal-programmable pull-up transistor and a metal-programmable pull-up transistor according to an embodiment of the present invention.

FIG. 4 illustrates a block diagram of an exemplary MPWWTM bias generator according to an embodiment of the present invention.

FIG. 5 illustrates a block diagram of another exemplary MPWWTM bias generator according to an embodiment of the present invention.

FIG. 6 illustrates a flow chart of a method of adjusting a set of available magnitudes of a bias voltage V_{bias} generated by a programmable weak write test mode (PWWTM) bias generator according to an embodiment of the present invention.

### MODES FOR CARRYING OUT THE INVENTION

A co-pending application for patent of Wuu, Stackhouse, and Weiss, (Wuu et al.) entitled “Programmable Weak Write Test Mode (PWWTM) Bias Generation Having Logic High Output Default Mode” is filed concurrently herewith (Attorney Docket No. 200207084-1), and is incorporated herein by reference in its entirety. The co-pending application describes a PWWTM bias generator and a WWTM-enabled SRAM system and a method that utilize the PWWTM bias generator. The PWWTM bias generator of the co-pending application addresses certain practical shortcomings of an integrated weak write test mode (WWTM) approach of Weiss et al., which is described above, with respect to a sizing sensitivity of a weak write pull-down transistor of a write driver of an SRAM. In particular, the PWWTM bias generator of the co-pending application provides a programmable bias voltage to drive the weak write pull-down transistor. The programmable bias voltage facilitates adjusting or modulating a strength of the weak write pull-down transistor that compensates for manufacturing related variations in a performance of the weak write pull-down transistor.

The present invention facilitates a range shift or modification and/or a resolution adjustment of a bias voltage output signal generated by a programmable weak write test mode (PWWTM) bias generator. The present invention employs metal programming to selectively add a transistor to the PWWTM bias generator during circuit manufacture. By selectively adding the transistor using metal programming, the range modifications and/or resolution adjustments are realized. A programmable bias voltage having the modified range and/or the adjustable resolution is employed to implement the WWTM of the SRAM.

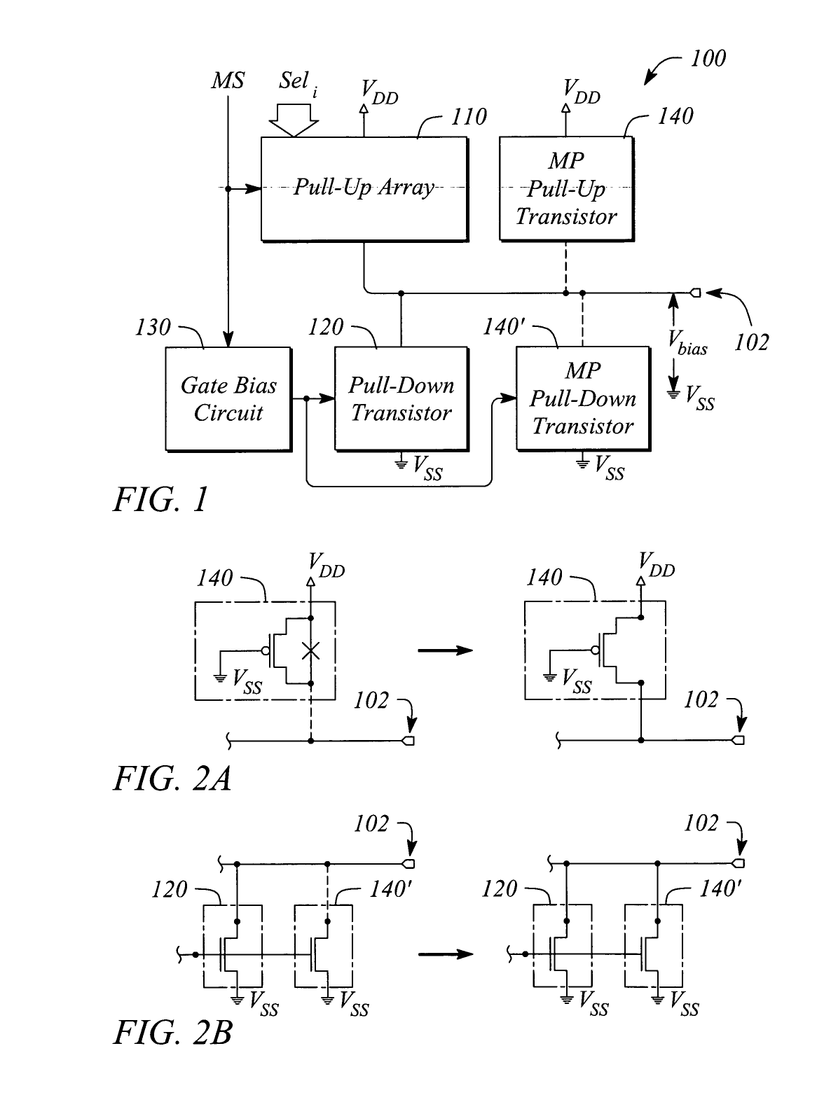

FIG. 1 illustrates a block diagram of a metal-programmable weak write test mode (MPWWTM) bias generator 100 according to an embodiment of the present invention. In particular, the MPWWTM bias generator 100 produces as an output signal a bias voltage V_{bias} at an output 102. The bias voltage V_{bias} has a magnitude that is selectable from among a set of available magnitudes. According to the present invention, the set of available magnitudes may be modified or adjusted using metal programming. For example, a range of the set of available magnitudes may be shifted through metal programming. In addition or alternatively, a resolution of or difference between magnitudes within the set may be adjusted through metal programming. Using metal programming to modify the set of available magnitudes may improve a likelihood that the MPWWTM bias generator 100 achieves a particular or desirable (preferably ‘an optimum’) target bias voltage for an associated WWTM-equipped SRAM without requiring a redesign of the MPWWTM bias generator 100.

As used herein, ‘metal programming’ refers to establishing and/or removing connections in an integrated circuit (IC) by changing a routing pattern of an interconnect layer, preferably a final or ‘top’ interconnect layer, of the IC during circuit fabrication. The final interconnect layer, in which metal programming is used to establish and/or remove connections, may be a metal layer such as, but not limited to, an aluminum layer of the IC. Alternatively, the final interconnect layer may employ a conductive polysilicon or an equivalent conductive material to provide interconnections within the IC. Metal programming allows routing or interconnection changes to be implemented with rapid ‘turn-around’ since the changes that may be made are typically pre-planned or anticipated during a design of the IC. To the extent that changes in the routing pattern affect a performance or functionality of the IC, the changes essentially ‘program’ the IC. Metal programming, sometimes referred to as ‘mask programming’, is familiar to one skilled in the art. For example, metal programming is often employed to program read only memory (ROM) ICs as well as to select specific functional configurations in some application specific integrated circuit (ASIC) and related IC implementations.

The MPWWTM bias generator 100 comprises a pull-up array 110 of array transistors typically p-type or p-channel metal oxide semiconductor (PMOS) transistors, a pull-down transistor 120 typically an n-type or n-channel metal oxide semiconductor (NMOS) transistor, and a gate bias circuit 130. The pull-up transistor array 110 is connected between a supply voltage V_{DD} and the output 102 of the MPWWTM bias generator 100. The pull-up array 110 has a set of selection inputs Selᵢ. The set of selection inputs Selᵢ are connected to the array transistors of the pull-up array 110 allowing one or more of the array transistors to be selectively activated or ‘turned ON’ by asserting one or more of the selection inputs Selᵢ.

The pull-down transistor 120 is connected between the output 102 and a second supply voltage V_{SS}, typically a ground voltage V_{SS}, of the MPWWTM bias generator 100. In particular, a source of the pull-down transistor 120 is connected to the output 102 and a drain of the pull-down transistor 120 is connected to the second supply voltage V_{SS}. An output of the gate bias circuit 130 is connected to a gate of the pull-down transistor 120.

The gate bias circuit 130 produces a gate bias voltage V_{g} that is applied to bias the gate of the pull-down transistor 120 to either activate or ‘turn ON’ (i.e., an ON state) or inactivate or ‘turn OFF’ (i.e., an OFF state) the transistor 120. A value of the gate voltage V_{g} depends on a mode select MS input to the MPWWTM bias generator 100. The mode select MS input selects between WWTM and a default mode, where WWTM is inactive. For example, in a particular embodiment, a logic high voltage level on the mode select MS input (i.e., MS=‘1’) causes the gate bias circuit 130 to produce a gate voltage V_{g} that turns ON the pull-down transistor 120. Alternatively, when the mode select MS input is a logic low voltage level (i.e., MS=‘0’), the gate bias circuit 130 produces a gate voltage V_{g} that turns OFF the pull-down transistor 120. When the pull-down transistor 120 is turned ON, the MPWWTM bias generator 100 operates in WWTM in conjunction with the associated SRAM. Alternatively, the MPWWTM bias generator 100 operates in a ‘default’ mode or non-WWTM when the pull-down transistor 120 is turned OFF.

The gate bias circuit 130 may be any circuit that produces the gate voltage V_{g} for turning ON and turning OFF the pull-down transistor 120 in response to the mode selection MS input. For example, the gate bias circuit 130 may be any of the gate bias circuits disclosed in the co-pending application for patent of Wuu et al., mentioned above. Similarly, the pull-up transistor array 110 may be any of the embodiments of the transistor array disclosed in the co-pending application of Wuu et al.

The MPWWTM bias generator 100 further comprises a metal-programmable (MP) transistor. In particular in some embodiments, the MP transistor comprises an MP pull-up transistor 140, preferably a PMOS transistor, which is selectively connectable in parallel with the pull-up array 110 through metal programming. In other embodiments, the MP transistor comprises an MP pull-down transistor 140′, preferably an NMOS transistor, which is selectively connected in parallel with the pull-down transistor 120 through metal programming. In yet other embodiments, the MP transistor comprises both the MP pull-up transistor 140 and the MP pull-down transistor 140′. The parallel connection of the MP pull-up transistor 140 and the pull-up transistor array 110 essentially decreases an ‘ON’ state resistance of a pull-up functionality provided by the pull-up transistor array 110 combined with the MP pull-up transistor 140. The parallel connection of the MP pull-down transistor 140′ and the pull-down transistor 120 essentially decreases the ON state resistance of a pull-down functionality provided by the pull-down transistor 120 combined with the MP pull-down transistor 140′.

Moreover, the MP pull-up transistor 140 may comprise one or more MP pull-up transistors, any one or more or all of which are selectively connectable in parallel with the array 110 through metal programming. When more than one MP pull-up transistors 140 is present, a particular one of the MP pull-up transistors 140 may be of a similar size to or a different size than one or more of the other MP pull-up transistors 140. Similarly, the MP pull-down transistor 140′ may comprise one or more MP pull-down transistors, any one or more or all of which are selectively connectable in parallel with the pull-down transistor 120. As with the MP pull-up transistor 140, when more than one MP pull-down transistors 140′ is present, a particular one of the MP pull-down transistors 140′ may be of a similar size to or a different size than one or more of the other MP pull-down transistors 140′.

In other embodiments, the MP pull-up transistor 140 may comprise an array of selectable MP pull-up transistors (not illustrated). Metal programming may be employed to disconnect the pull-up transistor array 110 from the MPWWTM bias generator 100 circuitry and replace the pull-up transistor array 110 with the array of selectable MP pull-up transistors (i.e., the ‘MP array’). Following metal programming, the MP array of selectable MP pull-up transistors essentially takes over a functionality of the pull-up transistor array 110.

Also in other embodiments, the MP pull-down transistor 140′ may comprise one or more transistors that through metal programming may replace the pull-down transistor 120. In particular, metal programming may be employed to disconnect the pull-down transistor 120 from the MPWWTM bias generator 100 circuitry and replace the pull-down transistor 120 with the one or more MP pull-down transistors 140′. Moreover, both the pull-up transistor array 110 and the pull-down transistor 120 may be replaced using metal programming with respective MP pull-up transistor(s) 140 and MP pull-down transistor(s) 140′ in some embodiments.

In yet other embodiments, the MP pull-up transistor 140 may be connected in series with one or more of the transistors of the pull-up transistor array 110 (not illustrated). The series connection of the MP pull-up transistor 140 and the pull-up transistor array 110 essentially increases the ON state resistance of a pull-up functionality provided by the pull-up transistor array 110 combined with the MP pull-up transistor 140. Similarly, the MP pull-down transistor 140′ may be connected in series with the pull-down transistor 120 (not illustrated). The series connection of the MP pull-down transistor 140′ and the pull-down transistor 120 essentially increases the ON state resistance of a pull-down functionality provided by the pull-down transistor 120 combined with the MP pull-down transistor 140′.

Referring again to FIG. 1, the MP pull-up transistor 140 is illustrated by a dashed line as selectively connectable in parallel with the pull-up transistor array 110 using metal programming during IC manufacture. By ‘selectively connectable’ it is meant that a decision whether or not to connect the MP pull-up transistor 140 can be made during IC manufacture. If the connection is selected, a particular metal interconnect layer routing configuration that interconnects the MP pull-up transistor 140 to the MPWWTM bias generator 100 circuitry is employed, for example. Alternatively, when the connection is not selected, the MP transistor 140 is preferably isolated from the MPWWTM bias generator 100 circuitry.

FIG. 2A illustrates a schematic of the MP pull-up transistor 140 of the MPWWTM bias generator 100 of FIG. 1 depicting a transition through metal programming from an exemplary ‘isolated’ configuration to a connected configuration. In particular, in a left side of FIG. 2A, the exemplary ‘isolated’ configuration of the MP pull-up transistor 140, when the MP pull-up transistor 140 is not connected to the MPWWTM bias generator 100 circuitry using metal programming, is illustrated. The isolated MP pull-up transistor 140 has a gate connected to ground V_{SS}, a drain connected the supply voltage V_{DD}, and a source connected the supply voltage V_{DD}. A heavy arrow pointing from left to right indicates metal programming. A right side of FIG. 2A illustrates a configuration of the MP pull-up transistor 140 after connection to the MPWWTM bias generator 100 circuitry through metal programming. A new connection is formed between the MP pull-up transistor 140 and the output 102 as indicated by a change from a ‘dashed’ line on the left side to a solid line on the right side of FIG. 2A. Concomitant with the formation of the new connection, the existing connection between the source of the MP pull-up transistor 140 and the supply voltage V_{DD} is removed, as indicated by the ‘X’ through the existing connection on the left side of FIG. 2A and the connection being nonexistent on the right side of FIG. 2A. Referring back to FIG. 1, a ‘dashed’ line connecting the MP pull-up transistor 140 and the output 102 indicates the same exemplary ‘metal-programmable’ connection that is illustrated as the dashed line in FIG. 2A. Thus, through metal programming, the MP pull-up transistor 140 is connected in parallel with the pull-up transistor array 110.

In another example, both the source and the drain of the MP pull-up transistor 140 are connected to the output 102 in the nominal case (not illustrated). Through metal programming the drain connection to the output 102 is replaced with a drain connection to the supply voltage V_{DD}. In yet another example, the drain and the gate may be connected to the supply voltage V_{DD} and the source may be connected to the output 102 in the nominal case (not illustrated). Metal programming replaces the gate-to-supply voltage V_{DD} connection with a gate-to-ground V_{SS} connection thereby turning ON the MP pull-up transistor 140. Alternatively, the gate-to-supply voltage V_{DD} connection may be replaced with a connection between the gate of the MP pull-up transistor 140 and one of the selection inputs Selᵢ (not illustrated). One skilled the art may readily devise numerous other metal-programmable configurations for selectively connecting the MP pull-up transistor 140 in parallel or in series with the pull-up array 110 (i.e., nominal case vs. metal-programmed case), all of which are within the scope of the present invention.

Regardless of implementation, in the nominal case, the MP pull-up transistor 140 is present in the bias generator 100 circuitry and not connected in parallel with the pull-up array 110, but is instead isolated from the bias generator 100 circuitry. As such, the MP pull-up transistor 140 has no effect on an operation of the bias generator 100. However, in the metal-programmed case, the connected MP pull-up transistor 140 acts in parallel with the pull-up array 110 to create the selectable magnitudes. In particular, in the nominal case, the selectable magnitudes of the bias voltage V_{bias} are a function of an effective resistance of the pull-up transistor array 110 and the ON state resistance of the pull-down transistor 120. In turn, the effective resistance of the pull-up transistor array 110 is a function of a number and a respective size of transistors in the array 110 that are activated or turned ON by the selection inputs Selᵢ. Thus, asserting one or more of the selection inputs Selᵢ, turns ON one or more of the array transistors and the turned-ON array transistors establish or determine the effective resistance of the pull-up array 110. Moreover, selecting the effective resistance of the pull-up transistor array 110 essentially selects a particular magnitude of the bias voltage V_{bias} from among a set of available magnitudes derived from the many different combinations of array transistors in the array 110 that are selectively turned ON.

On the other hand, in the metal-programmed case, the MP pull-up transistor 140 is connected to the MPWWTM bias generator 100 circuitry and the selectable magnitude of the bias voltage V_{bias} is a function of the ON state resistance of the MP pull-up transistor 140 as well as the effective resistance of the pull-up transistor array 110 and the ON state resistance of the pull-down transistor 120. In particular, when connected through metal programming, the MP pull-up transistor 140 acts in parallel with the pull-up array 110 to reduce the effective resistance of the pull-up array 110 in a manner essentially similar to that of connecting a second resistor in parallel with a first resistor. One skilled in the art is familiar with how connecting a second resistor in parallel with a first affects the combined resistance. Thus, a combined effective resistance of the pull-up transistor array 110 and the connected MP pull-up transistor 140 in conjunction with the resistance of the pull-down transistor 120 determine the modified set of available magnitudes of the bias voltage V_{bias}. One skilled in the art is also familiar with connecting resistors in series and its affect on the overall resistance thereof, which is applicable to other embodiments of the MP pull-up transistor 140 connected in series to the pull-up transistor array 110 of the present invention.

Referring once again to FIG. 1, the MP pull-down transistor 140′ is illustrated as selectively connectable in parallel with the pull-down transistor 120 using metal programming during IC manufacture using a dashed line connection to the output 102. As with the MP pull-up transistor 140, in the metal-programmed case, a particular metal interconnect layer routing configuration that connects the MP pull-down transistor 140′ to the MPWWTM bias generator 100 circuitry is employed. In the nominal case, the MP pull-down transistor 140′ is present in but is preferably isolated from the bias generator 100 circuitry. For example, the MP pull-down transistor 140′ may be have a gate connected to the output of the gate bias circuit 130 and a drain connected to ground V_{SS}. A source of the pull-down transistor 120′ may be open circuited (e.g., not connected to anything) in the nominal case. Through metal programming, a connection may be formed or added between the source and the output 102. The connection so formed essentially connects the MP transistor 140′ in parallel with the pull-down transistor 120.

FIG. 2B illustrates the MP pull-down transistor 140′ of the MPWWTM bias generator 100 of FIG. 1 depicting a transition through metal programming from an exemplary ‘isolated’ configuration to a connected configuration. In particular, on a left side of FIG. 2B, an exemplary ‘isolated’ configuration of the MP pull-down transistor 140′ is illustrated. The isolated MP pull-down transistor 140′ has a drain connected to ground V_{SS}, a gate connected to a gate of the pull-down transistor 120, and a source that is open circuited (i.e., not connected to anything). A heavy arrow pointing from left to right indicates metal programming. A right side of FIG. 2B illustrates a configuration of the MP pull-down transistor 140′ after connection to the MPWWTM bias generator 100 circuitry through metal programming. A new connection is formed between the source of the MP pull-down transistor 140′ and the output 102 as indicated by a dashed line on the left side and a solid line of the right side of FIG. 2B, respectively. Referring back to FIG. 1, the dashed line connecting the MP pull-down transistor 140′ and the output 102 indicates the same exemplary ‘metal-programmable’ connection that is illustrated as the dashed line in FIG. 2B. Thus, the MP pull-down transistor 140′ is connected in parallel with the pull-down transistor 120 to the MPWWTM bias generator 100 circuitry through metal programming.

In another example, the source of the MP pull-down transistor 140′ is connected to the output 102 while the drain and the gate are connected to ground V_{SS} in a nominal case (not illustrated). Metal programming is employed to replace the gate-to-ground V_{SS} connection with a connection between the gate and the gate bias circuit 130 output. One skilled in the art may readily devise other similar configurations for selectively connecting the MP pull-down transistor 140′ to the MPWWTM bias generator 100 circuitry in various nominal and metal-programmed cases, all of which are within the scope of the present invention. Moreover, as with the MP pull-up transistor 140, a variety of isolated configurations for the MP pull-down transistor 140′ are conceivable by one skilled in the art. All such isolated configurations are within the scope of the present invention.

As noted hereinabove, the MP pull-down transistor 140′ is present but isolated from and thus has no effect on an operation of the MPWWTM bias generator 100 in the nominal case. Thus, the effective resistance of the pull-up transistor array 110 and the ON state resistance of the pull-down transistor 120 determine the available magnitudes of the bias voltage V_{bias}. However, in the metal programming case, the MP pull-down transistor 140′ is connected in parallel with the pull-down transistor 120. As a result, the available magnitudes are determined by an ON state resistance of the MP pull-down transistor 140′ in addition to the effective resistance of the pull-up transistor array 110 and the ON state resistance of the pull-down transistor 120. In particular, the ON state resistance of the connected (or ‘metal programmed’) MP pull-down transistor 140′ acts in parallel with the ON state resistance of the pull-down transistor 120 to effectively lower a combined ON state resistance of the pull-down transistor 120 and the MP pull-down transistor 140′. Moreover, it is within the scope of the invention for the MP pull-down transistor 140′ to be connected in series with the pull-down transistor 120 through metal programming to affect the combined ON state resistance similarly to that of connecting two resistors in series.

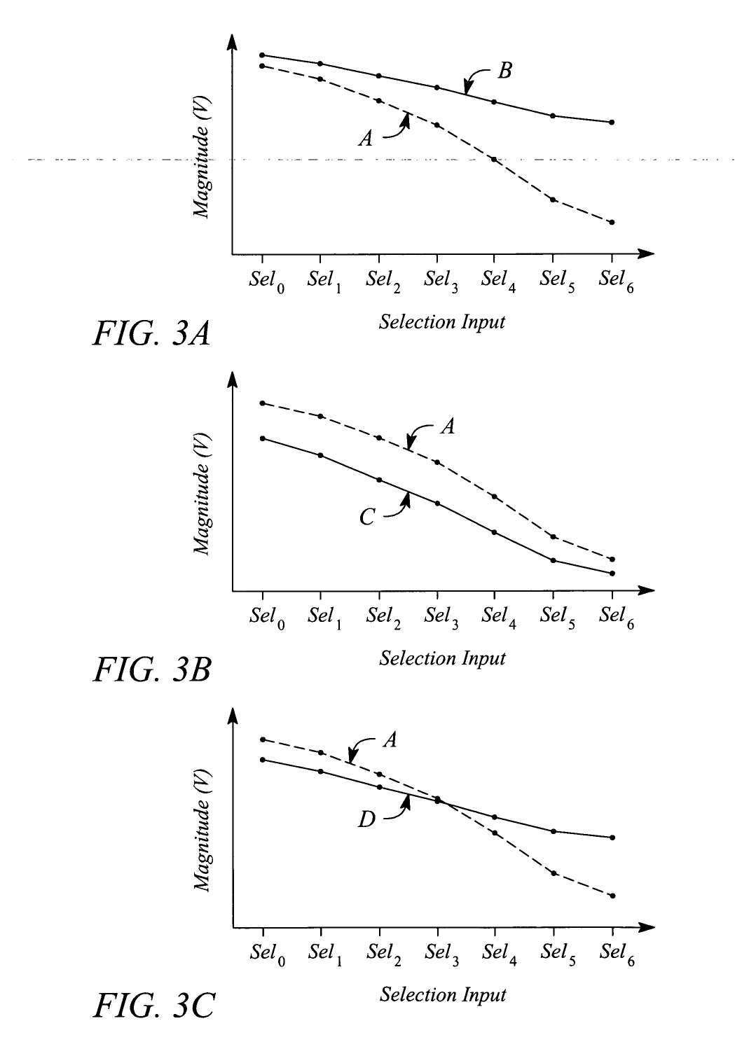

An example of modifying a set of available magnitudes of a bias voltage V_{bias} through metal programming of an MP pull-up transistor 140 according to an embodiment of the present invention is illustrated using a graph of magnitudes versus selection inputs in FIG. 3A. As illustrated in FIG. 3A, the pull-up transistor array 110 without the MP pull-up transistor 140 (i.e., nominal case) is employed to select between a first set (A) of available magnitudes of the bias voltage V_{bias}. Another set (B) of available magnitudes is produced when the MP pull-up transistor 140 is connected in parallel with the array 110 (i.e., metal-programmed case). The second set B is generally higher (i.e., has a higher median value) than the first set A since the parallel combination of the pull-up transistor array 110 and the MP pull-up transistor 140 represents a lower combined effective resistance than the effective resistance of the pull-up array 110 alone. Moreover as illustrated in FIG. 3A, the second set B generally spans a smaller overall range or extent of values than the first set A. As such, connection of the MP pull-up transistor 140 in parallel with the pull-up transistor array 110 essentially increases a resolution of the selectable magnitudes.

FIG. 3B illustrates a graphical example of modifying a set of available magnitudes of the bias voltage V_{bias} through metal programming of the MP pull-down transistor 140′ according to an embodiment of the present invention. As illustrated, the pull-down transistor 120 without the MP pull-down transistor 140′ may be employed to select between a first set (A) of available magnitudes of the bias voltage V_{bias}. Another set (C) of available magnitudes is produced with the MP pull-down transistor 140′ connected in parallel with the pull-down transistor 120 by metal programming. The second set C is generally lower (i.e., has a lower median value) than the first set A since the parallel combination of the pull-down transistor 120 and the MP pull-down transistor 140′ represent a lower combined ON state resistance than the ON state resistance of the pull-down transistor 120 alone. Thus, metal-programming the MP pull-down transistor 140′ in parallel with the pull-down transistor 120 facilitates shifting a range of the available magnitudes to a lower range.

FIG. 3C illustrates a graphical example of shifting a range of the available magnitudes and reducing a resolution of the available magnitudes of a generated bias voltage V_{bias} according to an embodiment of the present invention. In particular, as illustrated in FIG. 3C, metal programming is used to connect both the MP pull-up transistor 140 and the MP pull-down transistor 140′ in parallel with the respective pull-up transistor array 110 and pull-down transistor 120. A first set (A) of available magnitudes represents the nominal case, when both MP transistors 140, 140′ are not connected into the circuitry. Another set (D) represents the available magnitudes produced by connecting both MP transistors 140, 140′ into the MPWWTM bias generator 100 circuitry. Such metal programming connections ‘in series’ advantageously provide other range shifts and/or resolution modifications in accordance with the present invention.

Generally, whether or not metal programming is employed to connect the MP pull-up transistor 140 and/or MP pull-down transistor 140′ to the MPWWTM bias generator 100 circuitry depends on whether or not a target value for the bias voltage V_{bias} lies within, is ‘above’, or is ‘below’, the range of available magnitudes without metal programming. The target value depends on an operational characteristic of a static random access memory (SRAM) that is undergoing weak write mode testing using the MPWWTM bias generator 100. One skilled in the art may readily determine whether or not connecting the MP pull-up transistor 140 and/or the MP pull-down transistor 140′ using metal programming is advantageous and/or necessary for a given weak write mode test situation without undue experimentation.

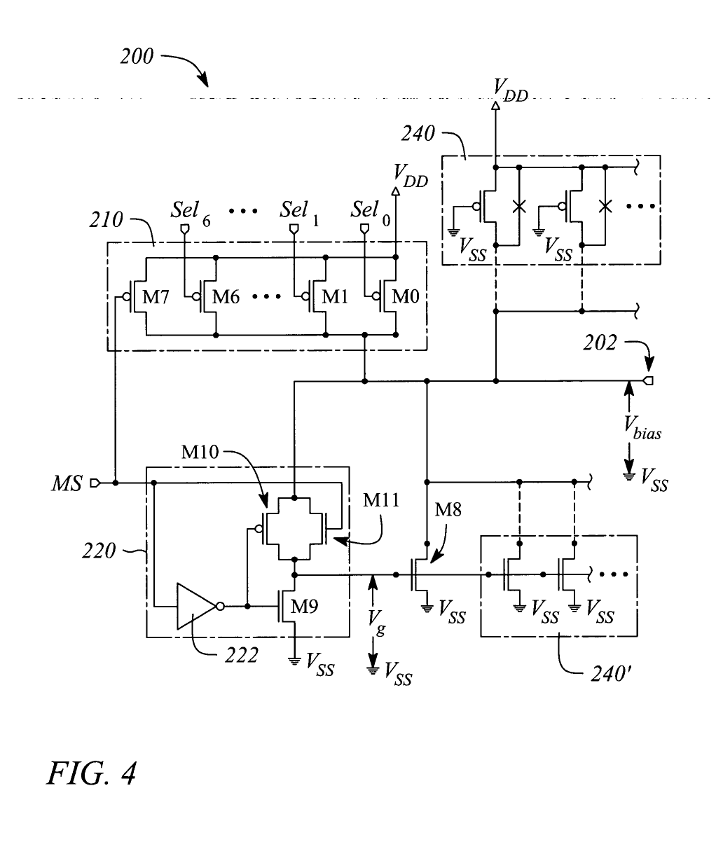

FIG. 4 illustrates a block diagram of an exemplary MPWWTM bias generator 200 according to an embodiment of the present invention. In particular, the MPWWTM 200 is based on the programmable weak write test mode (PWWTM) bias generator disclosed in the co-pending application for patent by Wu et al., cited above. For example, the MPWWTM bias generator 200 operates like the PWWTM bias generator disclosed by Wu et al., when the MP transistor is not connected. FIG. 4 illustrates a particular embodiment 200 of the MPWWTM bias generator 100 illustrated in FIG. 1 of the present invention. The MPWWTM bias generator 200 has a set of selection inputs Sel₁-Sel₇, a mode select MS input, and an output 202. When mode select MS is asserted (i.e., MS=‘1’), the MPWWTM bias generator 200 produces as an output signal a bias voltage V_{bias} having a selectable magnitude. The bias voltage V_{bias} output signal is produced at the output 202. The selectable magnitude is controlled by the selection inputs Sel₁-Sel₇ and is selectable from among a set of available magnitudes. When mode select MS is not asserted (i.e., MS=‘0’) the exemplary MPWWTM bias generator 200 produces an output signal representing a logic high ‘1’ level at the output 202. In other words, the exemplary MPWWTM bias generator 200 output signal defaults to logic high ‘1’ level when mode select MS does not assert WWTM (i.e., default mode). The co-pending application of Wuu et al. provides additional operational details of the PWWTM bias generator in a nominal case, without the metal programming and the presence of a MP transistor according to the present invention. Therefore, a discussion of the nominal case will be omitted herein in the interest of brevity.

The MPWWTM bias generator 200 comprises a pull-up array 210 of transistors M0-M7 typically PMOS transistors, a pull-down transistor M8, a gate bias circuit 220, and a metal-programmable (MP) transistor comprising either or both of one or more metal-programmable (MP) pull-up transistors 240 and one or more metal-programmable (MP) pull-down transistors 240′. The transistors M0-M7 of the array 210 are each connected between the first supply voltage V_{DD} and the output 202 of the MPWWTM bias generator 200. The pull-down transistor M8 has a source connected to the output 202 and a drain connected to the second supply voltage V_{SS}, typically ground.

The gate bias circuit 220 comprises an inverter 222, a first transistor M9 that is typically NMOS, a second transistor M10 that is typically PMOS, and a third transistor M11 that is typically NMOS. A source of the first transistor M9 is connected to a gate of the pull-down transistor M8 while a drain of the first transistor M9 is connected to ground V_{SS}. A drain of the second transistor M10 is connected to a source of the third transistor M11 and to the output 202 of the MPWWTM bias generator 200. A source of the second transistor M10 and a drain of the third transistor M11 are connected the gate of the pull-down transistor M8. The mode select MS input of the MPWWTM bias generator 200 is connected to an input of the inverter 222 and to a gate of the third transistor M11. An output of the inverter 222 is connected to a gate of the first transistor M9 and a gate of the second transistor M10.

Each of the MP pull-up transistors 240 is selectively connectable between the supply voltage V_{DD} and the output 202 as is indicated by the solid line and the dashed lines in FIG. 4, respectively. Also as illustrated in FIG. 4, the ‘X’ through a connection indicates a connection that is removed during metal programming. As such, any one of the MP pull-up transistors 240 or any combination of the MP pull-up transistors 240 may be independently and selectively connected in parallel with the pull-up transistor array 210 in this exemplary embodiment.

Each of the MP pull-down transistors 240′ has a gate connected to the gate of the pull-down transistor M8 and a drain connected to ground V_{SS} while a source is selectively connectable to the output 202 also indicated by dashed lines in FIG. 4. As such, any one of the MP pull-down transistors 240′ or any combination of the MP pull-down transistors 240′ may be independently and selectively connected in parallel with the pull-down transistor M8 in this exemplary embodiment.

In the metal-programmed case when the MP transistor is connected, the operation of the MPWWTM bias generator 200 is modified from the nominal case. In particular, a set of selectable magnitudes of the bias voltage V_{bias} is dependent on an effect of the selectively connected MP transistors 240, 240′, as described hereinabove with respect to the MP transistors 140, 140′ of the MPWWTM bias generator 100. For example, a metal programmed transistor comprising both the MP pull-up transistors 240 and the MP pull-down transistors 240′ enables a shift of certain ones of the available magnitudes either up or down through metal programming. Thus, a target voltage above or below a nominal range may be achieved through metal programming of either or both of the MP pull-up transistor 240 and the MP pull-down transistor 240′, for example. However, metal programming does not affect the operation of the exemplary MPWWTM bias generator 200 in the default mode. Metal programming advantageously affects only the WWTM.

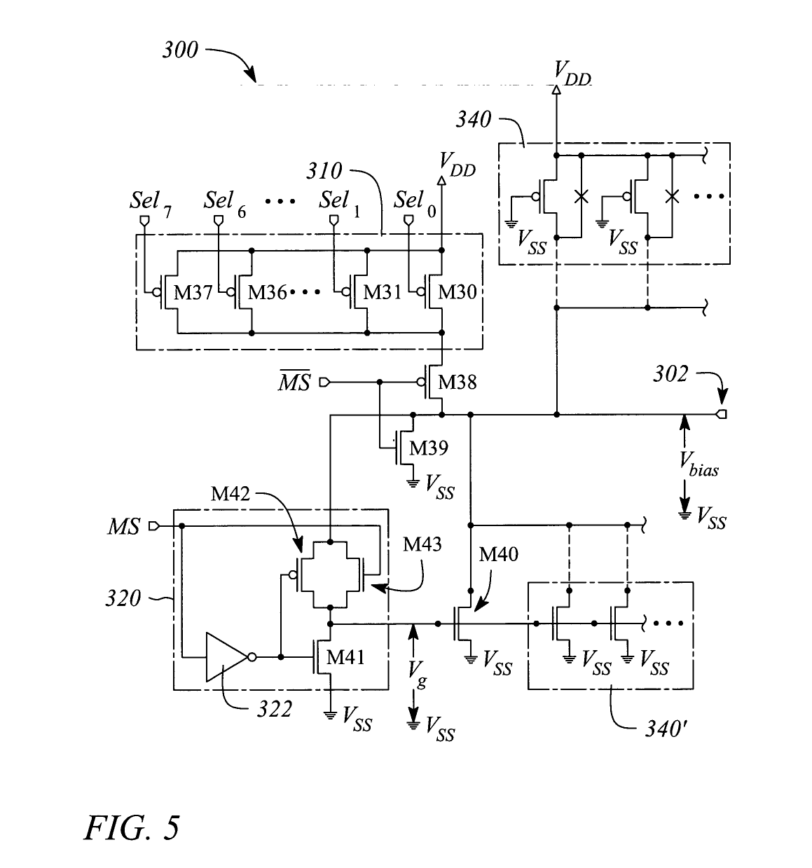

FIG. 5 illustrates a block diagram of another exemplary MPWWTM bias generator 300 according to an embodiment of the present invention. The exemplary MPWWTM bias generator 300 illustrated in FIG. 5 is based on a PWWTM generator circuit known in the art and described by Wuu et al. in the co-pending application. The MPWWTM bias generator 300 represents a particular embodiment of the MPWWTM bias generator 100 of FIG. 1, described hereinabove. The MPWWTM generator 300 has a set of selection inputs Sel₁-Sel₇, a mode select MS input, an inverse mode select \overline{MS} input, and an output 302. When mode select MS is asserted (i.e., MS=‘1’), the MPWWTM bias generator 300 produces at the output 302 a bias voltage V_{bias} that has a selectable magnitude as an output signal. The selectable magnitude is controlled by the selection inputs Sel₁-Sel₇ and is selectable from among a set of available magnitudes. When mode select MS is not asserted (i.e., MS=‘0’), the MPWWTM bias generator 300 produces a logic low ‘0’ level signal at the output 302. In other words, the PWWTM bias generator 300 output signal defaults to logic low ‘0’ when mode select MS is not asserted (i.e., a default mode, when WWTM is not active). Additional details regarding the operation of the PWWTM generator circuit known in the art without the present invention (i.e., in a nominal case without metal programming or the presence of the MP transistor of the present invention) are provided by Wuu et al. in the co-pending application and will be omitted herein in the interest of brevity

The PWWTM bias generator 300 comprises an array 310 of array transistors M30-M37 that are typically PMOS transistors. The sources of each of the array transistors M30-M37 are connected to the first supply voltage V_{DD}. A gate of each array transistors M30-M37 is connected to a different one of the selection inputs Sel₀-Sel₇. The array transistor M30 is a smallest or weakest transistor of the array 310 having a relatively highest ON state resistance while the array transistor M37 is a largest or strongest transistor of the array 310 having a relatively lowest ON state resistance.

The MPWWTM bias generator 300 further comprises a first transistor M38 that is typically PMOS and a second transistor M39 that is typically NMOS. A source of the first transistor M38 is connected to drains of each of the array transistors M0-M7 of the array 310. A drain of the first transistor M38 and a drain of the second transistor M39 are connected to the output 302 of the MPWWTM bias generator 300. A source of the second transistor M39 is connected to a second supply voltage V_{SS} that is typically ground. A gate of the first transistor M38 and a gate of the second transistor M39 are connected to the inverse mode select MS input of the MPWWTM bias generator 300.

The MPWWTM bias generator 300 further comprises a pull-down transistor M40 that is typically NMOS and that is typically weak, and a gate bias circuit 320. The pull-down transistor M40 has a drain connected to the output 302 and a source connected to ground V_{SS}. A gate of the pull-down transistor M40 is connected to an output of the gate bias circuit 320. The gate bias circuit 320 is essentially similar to the gate bias circuit 130, 220, described hereinabove. In particular, the gate bias circuit 320 comprises an inverter 322, a bias circuit pull-down transistor M41 that is typically NMOS, a first bias circuit transistor M42 that is typically PMOS, and a second bias circuit transistor M43 that is typically NMOS. A drain of the bias circuit pull-down transistor M41 is connected to the gate of the pull-down transistor M40 while a source of the transistor M41 is connected to ground V_{SS}. A source of the first bias circuit transistor M42 and a drain of the second bias circuit transistor M43 are connected together and connected to the output 302. A drain of the first bias circuit transistor M42 and a source of the second bias circuit transistor M43 are connected together and connected to the gate of the pull-down transistor M40. Together, first and second bias circuit transistors M42 and M43 form a transmission gate similar to the transmission gate described with respect to the gate bias circuit 220 hereinabove. An output of the inverter 322 is connected to a gate of the bias circuit pull-down transistor M41 and a gate of the first bias circuit transistor M42. An input of the inverter 322 and a gate of the second bias circuit transistor M43 are connected to the mode select MS input of the bias generator 300 for normal operation of the bias generator 300. The input of the inverter 322 is further connected to an eighth selection input Sel₇ of the bias generator 300 (not illustrated). As such, the eighth selection input Sel₇ is essentially equivalent to the mode select MS input for normal operation.

The exemplary MPWWTM bias generator 300 further comprises a metal-programmable (MP) transistor that comprises either or both of one or more metal-programmable (MP) pull-up transistors 340 that are typically PMOS and one or more metal-programmable (MP) pull-down transistor 340′ that are typically NMOS. Each of the MP pull-up transistors 340 may be selectively connected in parallel with the array transistors M30-M37 of the array 310 using metal programming as indicated by dashed lines from the MP pull-up transistors 340 in FIG. 5. Also as illustrated in FIG. 5, an ‘X’ through a line indicates a connection that is removed during metal programming. Each of the MP pull-down transistors 340′ may be selectively connected in parallel with the pull-down transistor M40 using metal programming also indicated by dashed lines from the MP pull-down transistors 340′ in FIG. 5. Furthermore, each of the MP pull-down transistors 340′ has a gate connected to the gate of the pull-down transistor M40 and each MP pull-down transistor 340′ acts in concert with the pull-down transistor M40 when connected through metal programming.

As with the MPWWTM bias generator 100 and the exemplary MPWWTM bias generator 200, the exemplary MPWWTM-bias generator 300 generally provides for shifting a range of the available magnitudes of the bias voltage V_{bias} through metal programming. By shifting the range of magnitudes, when the MPWWTM bias generator 300 is associated with, or connected to provide the bias voltage V_{bias} output signal to, an SRAM, a target value or magnitude of the bias voltage V_{bias} determined by the associated SRAM may be achieved more readily than without metal programming.

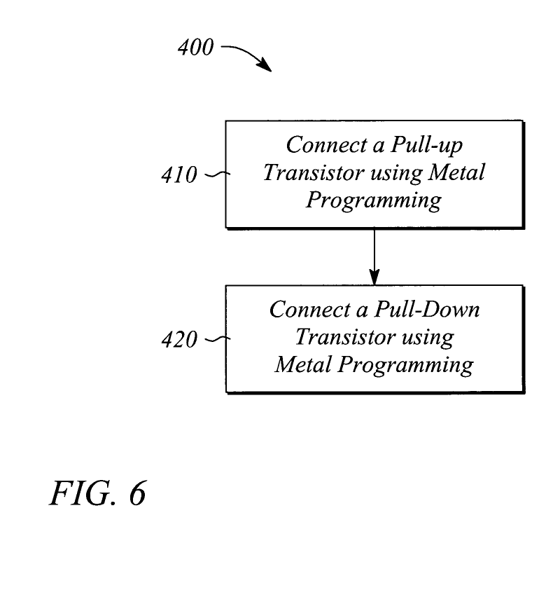

FIG. 6 illustrates a flow chart of a method 400 of modifying a set of available magnitudes of a bias voltage V_{bias} generated by a programmable weak write test mode (PWWTM) bias generator according to an embodiment of the present invention. The PWWTM bias generator provides the bias voltage V_{bias} to a static random access memory (SRAM) that is equipped to perform a weak write test. The provided bias voltage V_{bias} has a selectable magnitude that is selected from among the set of available magnitudes. For example, the PWWTM bias generator may be any of the PWWTM bias generators disclosed by Wuu et al. in the co-pending application. According to the present invention, the method 400 of modifying is used to modify or adjust the available magnitudes such that one or more of the available magnitudes better approximates a target voltage determined by the weak write test of the SRAM.

The method 400 of modifying comprises connecting 410 an auxiliary or metal-programmable (MP) pull-up transistor to circuitry of the PWWTM bias generator using metal programming. The auxiliary pull-up transistor is provided in the circuitry of the PWWTM bias generator during IC manufacture in some embodiments, but is provided in an isolated configuration. The auxiliary pull-up transistor is preferably a PMOS transistor although in some applications an NMOS transistor may be employed. In some embodiments, the auxiliary pull-up transistor is connected 410 in parallel with a pull-up transistor array of the PWWTM bias generator using metal programming. In other embodiments, the auxiliary pull-up transistor is connected in series with one or more of the array transistors of the pull-up array. In yet other embodiments, metal programming is employed to connect 410 a plurality of auxiliary pull-up transistors in series and in parallel with the pull-up transistor array.

Connecting 410 using metal programming combines an ON state resistance of the auxiliary pull-up transistor with an effective ON -state resistance of the pull-up transistor array to modify the available magnitudes of the generated bias voltage V_{bias} as described hereinabove with respect to the MPWWTM bias generator 100, 200, 300. Whether or not to actually connect 410 the auxiliary pull-up transistor (and which or how many to connect and how to connect them) depends on the target voltage of the SRAM. As such, connecting 410 represents a ‘potential for connecting’ in some embodiments and thus connecting 410 may be optionally applied in a given situation. Moreover, the connected 410 MP pull-up transistor may be selected from among a plurality of metal-programmable pull-up transistors provided in a particular implementation of the PWWTM bias generator. In particular, each MP pull-up transistor of the plurality of metal-programmable pull-up transistors may have a different size (i.e., produces a difference ON state resistance). Thus, connecting 410 comprises selecting an appropriate MP pull-up transistor of the plurality based on transistor size and then forming a connection with the selected MP pull-up transistor using metal programming.

The method 400 of modifying further comprises connecting 420 an auxiliary or MP pull-down transistor to the circuitry of the PWWTM bias generator using metal programming. The auxiliary pull-down transistor is provided in the circuitry of the PWWTM bias generator during IC manufacture in some embodiments, but is provided in an isolated configuration. The auxiliary pull-down transistor is preferably an NMOS transistor although in some applications a PMOS transistor may be employed. In some embodiments, the auxiliary pull-down transistor is connected 420 in parallel with a pull-down transistor of the PWWTM bias generator. In other embodiments, the auxiliary pull-down transistor is connected in series with the pull-down transistor. In yet other embodiments, metal programming is employed to connect 420 one or more of a plurality of auxiliary pull-down transistors in series and/or in parallel with the pull-down transistor.

Connecting 420 using metal programming combines an ON state resistance of the auxiliary MP pull-down transistor with an ON state resistance of the pull-down transistor to modify the available magnitudes of the generated bias voltage V_{bias} as described hereinabove with respect to the MPWWTM bias generator 100, 200, 300. Whether or not to actually connect 420 the auxiliary MP pull-down transistor depends on the target voltage of the SRAM. As such, connecting 420 represents a ‘potential for connecting’ in some embodiments and thus connecting 420 may be optionally applied in a given situation. Moreover, the connected 420 auxiliary pull-down transistor may be a MP pull-down transistor selected from among a plurality of auxiliary metal-programmable pull-down transistors provided in a particular implementation of the PWWTM bias generator. In particular, each MP pull-down transistor of the plurality of auxiliary metal-programmable pull-down transistors may have a different size (i.e., produce a different ON state resistance). Thus, connecting 420 comprises selecting one or more of an appropriate auxiliary pull-down transistor of the plurality based on transistor size and then forming a connection with the selected auxiliary pull-down transistor using metal programming. Important to the method 400 of modifying is that a metal-programmable transistor is provided in the PWWTM bias generator that may be selectively connected to the bias generator circuitry during IC manufacture. The provided metal-programmable transistor comprises either or both of the auxiliary MP pull-up transistor and the auxiliary MP pull-down transistor depending on the embodiment. Therefore, connecting 410, 420 is dependent on the embodiment of the metal-programmable PWWTM bias generator that is employed.

One or more of the following features and/or advantages may be realized by the present invention. The selective range shifts and/or resolution modifications of the programmable bias voltage signal level may be used to account for process variations in strength of a pull-down transistor of the SRAM. In particular by metal programming, the range shifting may better accommodate variations encountered in SRAM manufacturing than without metal programming, thereby reducing a need for iterative design adjustments and or redesigns of the bias generator circuit. Furthermore, the modifications may facilitate optimizing the level of the bias voltage output signal for WWTM testing of the SRAM. Either separately or together, selective, metal-programming-based range shifts and resolution adjustments may advantageously increase a manufacturing yield of the SRAMs.

Thus, there have been described embodiments of a bias generator that employs metal programming to modify a set of available magnitudes of the generated bias voltage V_{bias}. In addition, a method of modifying a set of available magnitudes of the generated bias voltages V_{bias} is disclosed. It should be understood that the above-described embodiments are merely illustrative of some of the many specific embodiments that represent the principles of the present invention. Clearly, those skilled in the art can readily devise numerous other arrangements without departing from the scope of the present invention as defined by the following claims.

What is claimed is:

1. A bias generator for testing of a static random access memory (SRAM) comprising:
means for adjusting a set of available magnitudes of a bias voltage output signal at an output the bias generator using metal programming.

2. The bias generator of claim 1, wherein the bias voltage output signal biases a gate of a weak write pull-down transistor of a write driver in the SRAM with a target magnitude predetermined for the SRAM.

3. The bias generator of claim 1, wherein the means for adjusting comprises a metal-programmable transistor in the bias generator, the metal-programmable transistor comprising either or both of a metal-programmable pull-up transistor and a metal-programmable pull-down transistor that change one or both of a range and a resolution of the set of available magnitudes when the metal-programmable transistor is metal programmed.

4. The bias generator of claim 3, further comprising:
a pull-up array of transistors connected between a first supply voltage and the bias generator output;
a pull-down transistor connected between the bias generator output and a second supply voltage; and
a gate bias circuit connected between a mode select input and a gate of the pull-down transistor,
wherein the metal-programmable pull-up transistor is connectable in parallel or in series with the pull-up transistor array, and
wherein the metal-programmable pull-down transistor is connectable in parallel or in series with the pull-down transistor.

5. The bias generator of claim 4, wherein each of the metal-programmable pull-up transistor and the metal-programmable pull-down transistor has a respective ON state resistance that, when either or both are metal programmed, combines with an effective ON state resistance of the pull-up transistor array and an ON state resistance of the pull-down transistor to adjust the set of available magnitudes.

6. A bias generator for testing of a static random access memory (SRAM) comprising:
a metal-programmable transistor that adjusts a set of available magnitudes of a bias voltage output signal at the bias generator output when metal programmed.

7. The bias generator of claim 6, further comprising:
a pull-up array of transistors connected between a first supply voltage and the bias generator output;
a pull-down transistor connected between the bias generator output and a second supply voltage; and
a gate bias circuit connected between a mode select input and a gate of the pull-down transistor,
wherein the metal-programmable transistor is connectable one or both of in series and in parallel with either or both of the pull-up array and the pull-down transistor.

8. The bias generator of claim 6, wherein the metal-programmable transistor comprises either or both of a metal-programmable pull-up transistor and a metal-programmable pull-down transistor, the metal-programmable transistor changing one or both of a range and a resolution of the set of available magnitudes when metal programmed.

9. The bias generator of claim 8, wherein the mode select input controls a selection between a weak write test mode (WWTM) and a default mode of operation of the bias generator, a set of selection inputs selecting the set of available magnitudes of the bias voltage output signal in the WWTM, the bias voltage output signal being a logic high level at the bias generator output in the default mode.

10. The bias generator of claim 8, further comprising:
a first transistor having a source connected to drains of the pull-up transistor array, a drain connected to the bias generator output, and a gate connected to an inverse mode select input; and
a second transistor having a source connected to the second supply voltage, a drain connected to the bias generator output, and a gate connected to the inverse mode select input,
wherein the mode select input and the inverse mode select input control a selection between a weak write test mode (WWTM) and a default mode of operation of the bias generator, a set of selection inputs selecting the set of available magnitudes of the bias voltage output signal in the WWTM, the bias voltage output signal being a logic low level at the bias generator output in the default mode.

11. The bias generator of claim 8, wherein the pull-up array transistors are p-type metal oxide semiconductor (PMOS) transistors that function to pull up the bias voltage output signal when in an ON state, and
wherein the pull-down transistor is an n-type metal oxide semiconductor (NMOS) transistor that functions to pull down the bias voltage output signal to the second supply voltage when in the ON state, the second supply voltage being less than the first supply voltage, the second supply voltage optionally being zero volts or a ground voltage.

12. A metal-programmable weak write test mode (MPWWTM) bias generator for weak write test mode (WWTM) testing of a static random access memory (SRAM) comprising:
a pull-up array of transistors connected between a first supply voltage and an output of the MPWWTM bias generator;
a pull-down transistor connected between the MPWWTM bias generator output and a second supply voltage;
a gate bias circuit connected between a mode select input and a gate of the pull-down transistor; and
a metal-programmable transistor that adjusts a set of available magnitudes of a bias voltage output signal at the MPWWTM bias generator output when metal programmed,
wherein the mode select input controls a selection between a WWTM and a default mode of operation of the MPWWTM bias generator, a set of selection inputs selecting the set of available magnitudes of the bias voltage output signal in the WWTM, the bias voltage output signal being a logic high level at the MPWWTM bias generator output in the default mode.

13. The MPWWTM bias generator of claim 12, wherein the pull-up array transistors are connected such that a source of each array transistor is connected to the first supply voltage, a drain of each array transistor is connected to the MPWWTM bias generator output, and a gate of each array transistor except for a gate of a last array transistor is connected to a different selection input of the set of selection inputs, the gate of the last array transistor being connected to the mode select input, and
wherein each of the pull-up array transistors is individually selectable and individually activatable, such that a particular selection and activation of the pull-up array transistors selects a particular magnitude of the set of available magnitudes for the bias voltage output signal in the WWTM.

14. The MPWWTM bias generator of claim 13, wherein the particular magnitude of the bias voltage is selected by asserting one or more of the selection inputs of the set that activate respective one or more array transistors of the pull-up array.

15. The MPWWTM bias generator of claim 12, wherein the metal-programmable transistor comprises either or both of a metal-programmable pull-up transistor and a metal-programmable pull-down transistor, the metal-programmable pull-up transistor being connectable one or both of in series and in parallel with the pull-up array the metal-programmable pull-down transistor being connectable one or both of in parallel and in series with the pull-down transistor, such that when metal programmed, the metal-programmed transistor changes one or both of a range and a resolution of the set of available magnitudes.

16. The MPWWTM bias generator of claim 15, wherein the metal-programmable pull-up transistor connects in parallel with the pull-up transistor array between the first supply voltage and the MPWWTM bias generator output when metal programmed, and
wherein the metal-programmable pull-down transistor connects between the MPWWTM bias generator output and the second supply voltage when metal programmed.

17. A metal-programmable weak write test mode (MPWWTM) bias generator for weak write test mode (WWTM) testing of a static random access memory (SRAM) comprising:
a pull-up array of transistors connected between a first supply voltage and an output of the MPWWTM bias generator;
a pull-down transistor connected between the MPWWTM bias generator output and a second supply voltage;
a gate bias circuit connected between a mode select input and a gate of the pull-down transistor;
a first transistor having a source connected to drains of the transistors of the pull-up array, a drain connected to the MPWWTM bias generator output, and a gate connected to an inverse mode select input;
a second transistor having a source connected to the second supply voltage, a drain connected to the MPWWTM bias generator output, and a gate connected to the inverse mode select input; and
a metal-programmable transistor that adjusts a set of available magnitudes of a bias voltage output signal at the MPWWTM bias generator output when metal programmed,
wherein the mode select input and the inverse mode select input control a selection between a WWTM and a default mode of operation of the MPWWTM bias generator, a set of selection inputs selecting the set of available magnitudes of the bias voltage output signal in the WWTM, the bias voltage output signal being a logic low level at the MPWWTM bias generator output in the default mode.

18. The MPWWTM bias generator of claim 17, wherein the pull-up array transistors are connected such that a source of each array transistor is connected to the first supply voltage, the drain of each array transistor is connected to the source of the first transistor, and a gate of each array transistor is connected to a different selection input of the set of selection inputs, and
wherein each of the pull-up array transistors is individually selectable and individually activatable, such that a particular selection and activation of the pull-up array transistors selects a particular magnitude of the set of available magnitudes for the bias voltage output signal.

19. The MPWWTM bias generator of claim 18, wherein the particular magnitude of the bias voltage is selected by asserting one or more of the selection inputs of the set that activate respective one or more array transistors of the array.

20. The MPWWTM bias generator of claim 17, wherein the metal-programmable transistor comprises either or both of a metal-programmable pull-up transistor and a metal-programmable pull-down transistor, the metal-programmable pull-up transistor being connectable one or both of in parallel and in series with the pull-up transistor array, the metal-programmable pull-down transistor being connectable one or both of in parallel and in series with the pull-down transistor, such that when metal programmed, the metal-programmed transistor changes one or both of a range and a resolution of the set of available magnitudes.

21. A method of modifying a set of available magnitudes of a bias voltage output signal generated by a bias generator comprising:
providing a metal-programmable transistor in the bias generator; and
metal programming the metal-programmable transistor to connect the transistor to circuitry of the bias generator, such that a corresponding ON state resistance of the metal-programmed transistor is combined with an effective ON state resistance of the circuitry to modify the available magnitudes of the set.

22. The method of modifying of claim 21, wherein providing a metal-programmable transistor comprises providing either or both of a metal-programmable pull-up transistor and a metal-programmable pull-down transistor in the bias generator, and
wherein metal programming the metal-programmable transistor comprises connecting either or both of the metal-programmable pull-up transistor and the metal-programmable pull-down transistor to the bias generator circuitry.

23. The method of modifying of claim 22, wherein metal programming the metal-programmable pull-up transistor to connect to the circuitry combines a corresponding pull-up ON state resistance of the metal-programmed pull-up transistor with an effective ON state resistance of a pull-up transistor array of the bias generator circuitry.

24. The method of modifying of claim 22, wherein metal programming the metal-programmable pull-down transistor to connect to the circuitry combines a corresponding pull-down ON state resistance of the metal-programmed pull-down transistor with an ON state resistance of a pull-down transistor of the bias generator circuitry.

25. The method of modifying of claim 22, wherein providing a metal-programmable transistor comprises providing either or both of a selection of metal-programmable pull-up transistors and a selection of metal-programmable pull-down transistors in the bias generator, at least one of the metal-programmable transistors of each respective selection being different from other metal-programmable transistors of the respective selections, and
wherein metal programming the metal-programmable transistor comprises selecting a respective metal-programmable transistor from either or both the pull-up transistor selection and the pull-down transistor selection, and connecting the selected respective metal-programmable transistor to the bias generator circuitry.
